(19) United States
(12) Patent Application Publication
(10) Pub. No.: US 2025/0390621 A1
(43) Pub. Date: Dec. 25, 2025

(54) DETERMINING BUILDING DAMAGE POTENTIAL FROM WILDLAND FIRE

(71) Applicant: Technosylva, Inc., La Jolla, CA (US)

(72) Inventors: Adrián Cardil Forradellas, Binéfar (ES); Santiago Daniel Monedero Timón, Madrid (ES); Joaquin Ramirez Cisneros, La Jolla, CA (US)

(21) Appl. No.: 18/754,052

(22) Filed: Jun. 25, 2024

(51) Int. Cl. G06F 30/13; G06F 30/27

(52) U.S. Cl. CPC G06F 30/13; G06F 30/27

(57) ABSTRACT

A service inputs building characteristics for a building into a machine learning model configured to output a probability that a given building will be lost should a fire reach the building, and receives as output from the model a building loss factor for the building. The service determines determining an exposure measurement for the building by performing simulations, over a plurality of candidate environmental parameters, of whether a simulated fire would encroach on the building. The service determines a building damage potential measurement based on the building loss factor, the exposure measurement, and an intensity measurement, and generates for display a graphical user interface showing fire risk for the building based on the building damage potential measurement.

### TECHNICAL FIELD

Aspects of this disclosure generally relate to the field of forecasting weather events, and more particularly relate to a machine learning approach to determining building damage potential from fire.

### BACKGROUND

Buildings are increasingly susceptible to damage from fire, especially during extreme weather events (e.g., during major wind events, drought periods, lightning storms, and so on). For example, wildfires have become more and more prevalent in certain regions. Given the uncertain nature of wildfires in terms of where they might start, intensity, rate of spread, and other factors, it is difficult to predict how wildfires might damage buildings. This clouds risk assessments for whether to take certain actions (e.g., mitigate fire ignition risks, take defensive space action, etc.).

### SUMMARY

Systems and methods are disclosed herein for determining and utilizing a metric measuring Building Damage Potential (BDP). BDP is a spatially variable metric, calculated on a building-by-building basis, that estimates the potential for building loss or damage, characterizing buildings in different levels of risk with a quantitative assessment. This metric is derived by fusing a measurement of a likelihood that a building will be lost if a fire is to reach it, as well as modeling of wildfire spread across a landscape in a vicinity of a building, including risks of fire encroachment into an urban area. BDP can be toggled depending on predicted fire intensity (e.g., with lower intensity in colder months and higher intensity in hotter months).

In some embodiments, a wildfire forecasting tool accesses a building loss factor measurement for a building. The building loss factor measurement may be determined by inputting building characteristics (e.g., and also potentially including characteristics about vegetation (fuel type), landform (building in a valley low on a slope, high on a slope, etc.), building density, etc.) for the building into a machine learning model, and receiving, as output from the machine learning model, the building loss factor measurement. The wildfire forecasting tool may access an exposure measurement for the building, the exposure measurement determined by performing a plurality of simulations that simulate, over a plurality of candidate environmental parameters, whether a fire would encroach on the building, and smoothing results of the plurality of simulations. The wildfire forecasting tool may determine a building damage potential measurement based on the building loss factor, the exposure measurement, and an intensity measurement, and may generate for display a graphical user interface showing fire risk for the building based on the building damage potential measurement.

### BRIEF DESCRIPTION OF DRAWINGS

The disclosed embodiments have other advantages and features which will be more readily apparent from the detailed description, the appended claims, and the accompanying figures (or drawings). A brief introduction of the figures is below.

FIG. 1 illustrates one embodiment of a system environment for implementing a wildfire forecast tool.

FIG. 2 illustrates one embodiment of modules used by the wildfire forecast tool.

FIG. 3 is an exemplary flowchart illustrating a process for obtaining information gain while using reduced ensemble members in an ensemble filter for forecasting weather events, in accordance with an embodiment.

### DETAILED DESCRIPTION

The Figures (FIGS.) and the following description relate to preferred embodiments by way of illustration only. It should be noted that from the following discussion, alternative embodiments of the structures and methods disclosed herein will be readily recognized as viable alternatives that may be employed without departing from the principles of what is claimed.

Reference will now be made in detail to several embodiments, examples of which are illustrated in the accompanying figures. It is noted that wherever practicable similar or like reference numbers may be used in the figures and may indicate similar or like functionality. The figures depict embodiments of the disclosed system (or method) for purposes of illustration only. One skilled in the art will readily recognize from the following description that alternative embodiments of the structures and methods illustrated herein may be employed without departing from the principles described herein.

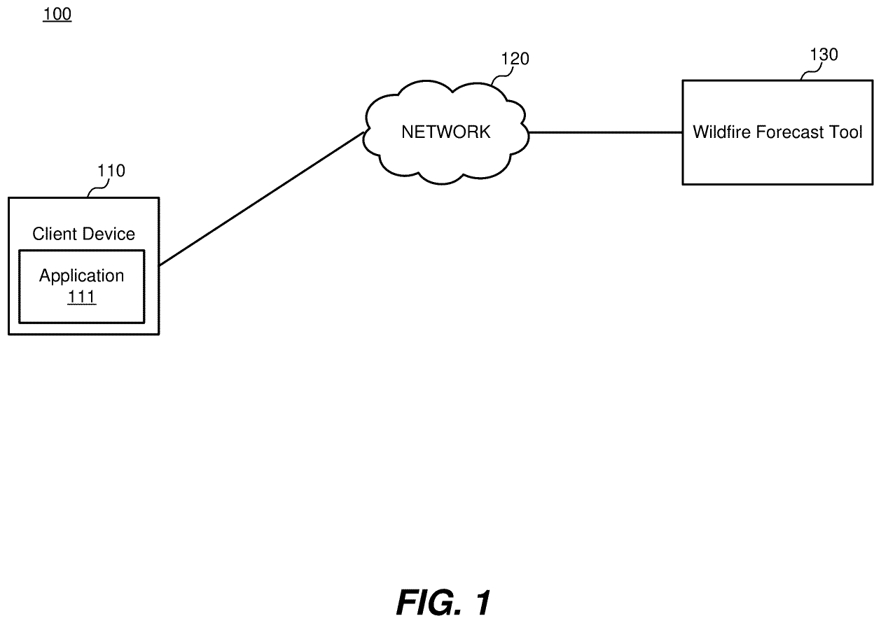

Figure (FIG. 1 illustrates one embodiment of a system environment for implementing a wildfire forecast tool. As depicted in FIG. 1, environment 100 includes client device 110 with application 111 installed thereon, network 120, weather forecast tool 130, and weather models 140. Client device 110 may be any device having a user interface useable to interact with wildfire forecast tool 130 via application 111. Exemplary client devices may include personal computers, laptops, tablets, smartphones, and so on. While only one client device 110 is depicted, any number of client devices may be used. Multiple client devices may be used at a same time to access and otherwise collaborate on forming a wildfire forecast. The term wildfire, as used herein, may refer to any fire unintentionally spreading through civilization (e.g., a fire started of unknown causes, from lightning strike, from a utility outage, from an explosion, from negligent human behavior, or from any other cause).

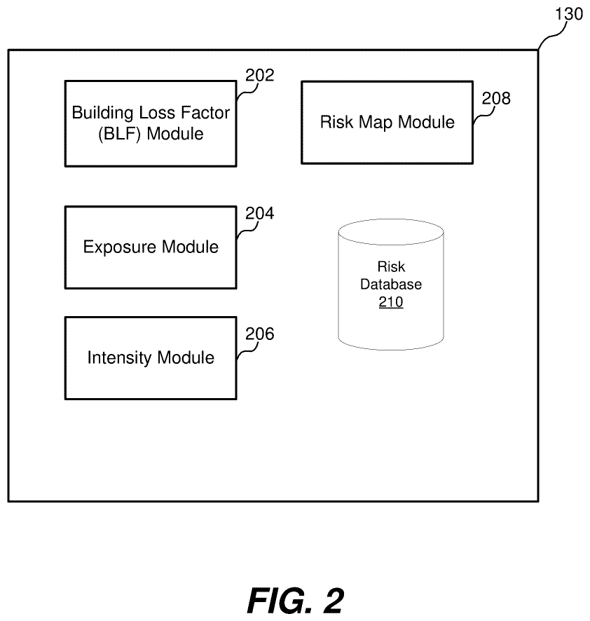

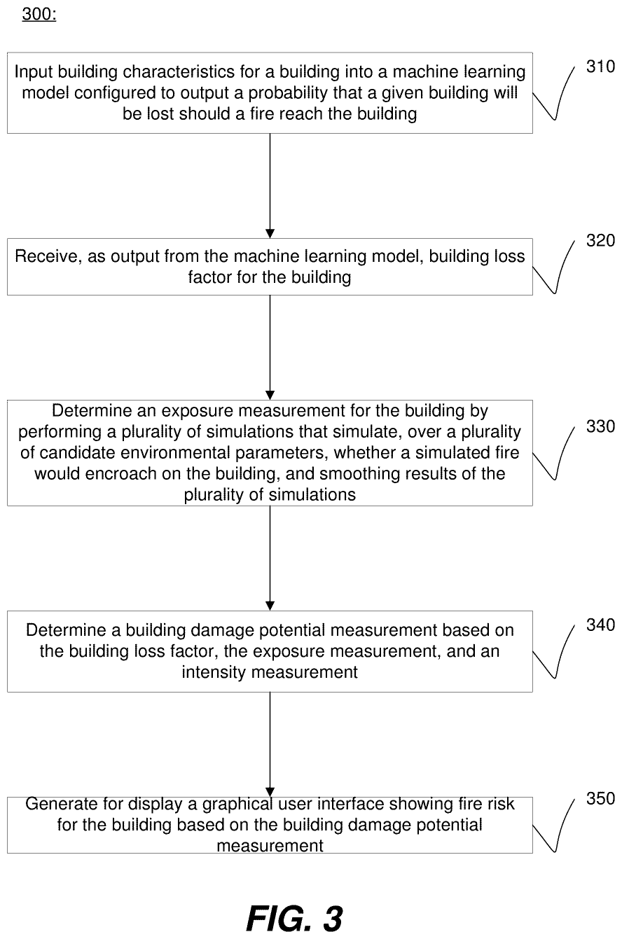

Application 111 may be a dedicated application installed on client device 110 that is configured to output information indicative of a wildfire forecast. Application 111 may be installed directly or indirectly from wildfire forecast tool 130 (e.g., downloaded from wildfire forecast tool 130; downloaded from an application store; from a hard drive having installation code, and so on). Any wildfire forecast activities may in whole or in part be performed on client device 110 by application 111 or may be performed in the cloud (e.g., using notebook tool 130). Application 111 may be a browser through which weather forecast functionality may be accessed from wildfire forecast tool 130. Details on activities of client device 110 and application 111 are discussed in further detail below with reference to FIGS. 2-3.

Network 120 may be a data communication channel between client device 110 and weather forecast tool 130. The data communication channel may be any channel usable to transmit communications between these entities, such as the Internet, a local area network, a wireless network, a short-range communications network, and so on. Network 120 may facilitate communication between any number of client devices and external servers and services beyond those depicted in environment 100.

Wildfire forecast tool 130 may be a cloud-based provider takes various parameters as an input and provides a forecast for an outcome of a wildfire event based on those parameters as described herein. More particularly, wildfire forecast tool 130 may be used to determine a potential that a building is lost in a wildfire, a potential that a building is damaged in a wildfire, a potential impact of a wildfire on a building, a potential that a wildfire might reach a building, and so on. All functionality described herein with respect to application 111 may be performed by wildfire forecast tool 130, and all functionality described herein with respect to wildfire forecast tool 130 may be performed by application 111. Distributed processing where some activity described is performed by 111 and other activity described is performed by wildfire forecast tool 130 is implied as within the scope of what is described even where processing is only described with respect to one of the two entities herein. Further details about the functionality of wildfire forecast tool 130 are described below with respect to FIG. 2.

FIG. 2 illustrates one embodiment of modules used by the wildfire forecast tool. As depicted in FIG. 2, wildfire forecast tool 130 includes Building Loss Factor (BLF) module 202, exposure module 204, intensity module 206, risk map module 208, and risk database 210. The modules and databases depicted in FIG. 2, and more or fewer modules and/or databases may be used to achieve the functionality disclosed herein.

BLF module 202 determines a building loss factor for a given building. The term building loss factor, as used herein, may refer to a probability of loss of a building in an extreme weather event involving a wildfire. Loss of the building may be defined as impact to a building that is more severe than having a burn scar when a fire reaches the building (e.g., structural impacts, loss of interior of building, and so on). BLF module 202 determines the building loss factor by inputting building characteristics for a building into a machine learning model configured to output a probability that a given building will be lost should a fire reach the building, and receiving, as output from the machine learning model, the building loss factor for the building.

The machine learning model used to predict the building loss factor is trained using training examples corresponding to buildings having been exposed to historical wildfires. Each training example has building characteristics, such as properties of the building (e.g., material of building, siding information, etc.), and characteristics of surroundings of the building (e.g., fields surrounding the buildings, landscape topography, building density, vegetation types, etc.). Each training example is labeled with whether the building experienced loss as a result of the historical wildfire. The machine learning model is thereby trained to predict a probability of loss for a new example of a building.

Exposure module 204 determines an exposure measurement for a given building by performing a plurality of simulations that simulate, over a plurality of candidate environmental parameters, whether a simulated fire would encroach on the building. The exposure measurement represents a probability of whether a fire would reach the given building. The simulations take inputs of any number of variables, such as where a fire originates, weather conditions (e.g., wind direction and force, heat, etc.), fuel conditions (e.g., type of material that a fire may burn through to reach the given building), landscape conditions (e.g., slope and other topography factors), obstacles (e.g., nearby buildings), likelihood of intervention (e.g., based on distance to a nearest fire department), and so on. The variables are input into a function that outputs whether the fire would reach the given building. Each simulation of the plurality of simulations may be perturbed by applying a random stochastic change to one or more of the variables. Exposure module 204 smooths the results of the simulations into an exposure measurement (e.g., by determining a frequency, over the plurality of simulations, with which the fire reached the building). Further details on how to determine an exposure measurement are described in “A Wildfire Risk Assessment Framework for Land and Resource Management,” Authored by Joe Scott et al., published in October 2013, a copy of which is submitted with this filing, and the disclosure of which is hereby incorporated by reference herein in its entirety.

Intensity module 206 determines a prediction of an intensity of a wildfire at a given time based on environmental conditions. As one non-limiting example, during summer conditions, a wildfire is likely to have a much more intense flame than in winter conditions. Many other factors can influence intensity including wind speed, drought, phenological vegetation status, and so on. The simulations run by exposure module 204 may be run with an estimate of an average flame length over the plurality of simulations, usually named conditional flame length (e.g., 3 feet). Intensity module 206 may determine a bias, based on a time of year, to apply to the modulate the probability of building loss measurement from module 202. The bias increases the likelihood of loss for simulations during conditions where flame length is expected to be high, and decreases the likelihood of exposure for simulations where flame length is expected to be low.

Risk map module 208 determines a building damage potential measurement based on the building loss factor, the exposure measurement, and an intensity measurement. For example, risk map module 208 may input, for a given building, its building loss factor, exposure measurement, and intensity measurement into a function. The function may output the building damage potential measurement. In some embodiments, the function may be a probabilistic model that aggregates the building loss factor, exposure measurement, and intensity into a measure of building damage potential. In some embodiments, the function may be a machine learning model trained using training examples from historical wildfires of their building loss factor, exposure measurements, and intensities, as labeled with a measure of how much damage the wildfire caused. The machine learning model may take as input the building loss factor, exposure measurement, and intensity and may output the building damage potential measurement. In some embodiments, the building damage potential measurement may be determined by multiplying together the building loss factor, exposure measurement, and intensity.

Wildfire forecast tool 130 may generate a BDP measurement for all known buildings (e.g., globally or within a particular region) to be stored for retrieval at a later time. Additionally or alternatively, wildfire forecast tool 130 may generate the component measurements (e.g., BLF, exposure, and intensity) for all known buildings to be stored for retrieval at a later time. Risk map module 208 may store the BDP measurements and/or the component measurements to risk database 210. The stored BDP measurements and/or component measurements may be refreshed by wildfire forecast tool 130 from time to time (e.g., periodically, given certain trigger events (e.g., change in expected weather conditions), or based on some other heuristic).

Risk map module 208 may generate for display a graphical user interface showing fire risk based on the BDP measurement. The fire risk may be determined on-the-fly by determining each component measurement of BDP and determining the BDP measurement therefrom. The fire risk may be determined by referencing risk database 210 for component measurements and determining the BDP therefrom. The fire risk may be determined by referencing risk database 210 for the BDP measurement directly. In some embodiments, risk map module 208 may determine a time of year associated with a request (e.g., determine wildfire risk operationally anytime), and may retrieve the BDP measurement and/or component measurements and weight the BDP measurement based on the intensity measurement.

Risk map module 208 may determine BDP for a plurality of buildings and output a map showing BDP for the plurality of buildings. For example, BDP may be categorized in terms of risk (e.g., low, medium, might), where each risk category defines a range of BDP, and where the map shows a set of pixels for each building that is coded (e.g., color coded) based on category.

FIG. 3 is an exemplary flowchart illustrating a process for obtaining information gain while using reduced ensemble members in an ensemble filter for forecasting weather events, in accordance with an embodiment. Process 300 may be executed by one or more processors instructing modules of wildfire forecast tool 130 to perform the operations of process 300. Process 300 may begin by wildfire forecast tool 130 inputting 310 building characteristics for a building into a machine learning model configured to output a probability that a given building will be lost should a fire reach the building (e.g., using BLF module 202).;

Wildfire forecast tool 130 receives 320, as output from the machine learning model, building loss factor for the building (e.g., using BLF module 202). Wildfire forecast tool 130 determines 330 an exposure measurement for the building by performing a plurality of simulations that simulate, over a plurality of candidate environmental parameters, whether a simulated fire would encroach on the building, and smooths results of the plurality of simulations (e.g., using exposure module 204). Wildfire forecast tool 130 determines 340 a building damage potential measurement based on the building loss factor, the exposure measurement, and an intensity measurement (e.g., using intensity module 206 and risk map module 208). Wildfire forecast tool 130 generates for display 350 a graphical user interface showing fire risk for the building based on the building damage potential measurement.

### Additional Configuration Considerations

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Certain embodiments are described herein as including logic or a number of components, modules, or mechanisms. Modules may constitute either software modules (e.g., code embodied on a machine-readable medium or in a transmission signal) or hardware modules. A hardware module is tangible unit capable of performing certain operations and may be configured or arranged in a certain manner. In example embodiments, one or more computer systems (e.g., a standalone, client or server computer system) or one or more hardware modules of a computer system (e.g., a processor or a group of processors) may be configured by software (e.g., an application or application portion) as a hardware module that operates to perform certain operations as described herein.

In various embodiments, a hardware module may be implemented mechanically or electronically. For example, a hardware module may comprise dedicated circuitry or logic that is permanently configured (e.g., as a special-purpose processor, such as a field programmable gate array (FPGA) or an application-specific integrated circuit (ASIC)) to perform certain operations. A hardware module may also comprise programmable logic or circuitry (e.g., as encompassed within a general-purpose processor or other programmable processor) that is temporarily configured by software to perform certain operations. It will be appreciated that the decision to implement a hardware module mechanically, in dedicated and permanently configured circuitry, or in temporarily configured circuitry (e.g., configured by software) may be driven by cost and time considerations.

Accordingly, the term “hardware module” should be understood to encompass a tangible entity, be that an entity that is physically constructed, permanently configured (e.g., hardwired), or temporarily configured (e.g., programmed) to operate in a certain manner or to perform certain operations described herein. As used herein, “hardware-implemented module” refers to a hardware module. Considering embodiments in which hardware modules are temporarily configured (e.g., programmed), each of the hardware modules need not be configured or instantiated at any one instance in time. For example, where the hardware modules comprise a general-purpose processor configured using software, the general-purpose processor may be configured as respective different hardware modules at different times. Software may accordingly configure a processor, for example, to constitute a particular hardware module at one instance of time and to constitute a different hardware module at a different instance of time.

Hardware modules can provide information to, and receive information from, other hardware modules. Accordingly, the described hardware modules may be regarded as being communicatively coupled. Where multiple of such hardware modules exist contemporaneously, communications may be achieved through signal transmission (e.g., over appropriate circuits and buses) that connect the hardware modules. In embodiments in which multiple hardware modules are configured or instantiated at different times, communications between such hardware modules may be achieved, for example, through the storage and retrieval of information in memory structures to which the multiple hardware modules have access. For example, one hardware module may perform an operation and store the output of that operation in a memory device to which it is communicatively coupled. A further hardware module may then, at a later time, access the memory device to retrieve and process the stored output. Hardware modules may also initiate communications with input or output devices, and can operate on a resource (e.g., a collection of information).

The various operations of example methods described herein may be performed, at least partially, by one or more processors that are temporarily configured (e.g., by software) or permanently configured to perform the relevant operations. Whether temporarily or permanently configured, such processors may constitute processor-implemented modules that operate to perform one or more operations or functions. The modules referred to herein may, in some example embodiments, comprise processor-implemented modules.

Similarly, the methods described herein may be at least partially processor-implemented. For example, at least some of the operations of a method may be performed by one or processors or processor-implemented hardware modules. The performance of certain of the operations may be distributed among the one or more processors, not only residing within a single machine, but deployed across a number of machines. In some example embodiments, the processor or processors may be located in a single location (e.g., within a home environment, an office environment or as a server farm), while in other embodiments the processors may be distributed across a number of locations.

The one or more processors may also operate to support performance of the relevant operations in a “cloud computing” environment or as a “software as a service” (SaaS). For example, at least some of the operations may be performed by a group of computers (as examples of machines including processors), these operations being accessible via a network (e.g., the Internet) and via one or more appropriate interfaces (e.g., application program interfaces (APIs).)

The performance of certain of the operations may be distributed among the one or more processors, not only residing within a single machine, but deployed across a number of machines. In some example embodiments, the one or more processors or processor-implemented modules may be located in a single geographic location (e.g., within a home environment, an office environment, or a server farm). In other example embodiments, the one or more processors or processor-implemented modules may be distributed across a number of geographic locations.

Some portions of this specification are presented in terms of algorithms or symbolic representations of operations on data stored as bits or binary digital signals within a machine memory (e.g., a computer memory). These algorithms or symbolic representations are examples of techniques used by those of ordinary skill in the data processing arts to convey the substance of their work to others skilled in the art. As used herein, an “algorithm” is a self-consistent sequence of operations or similar processing leading to a desired result. In this context, algorithms and operations involve physical manipulation of physical quantities. Typically, but not necessarily, such quantities may take the form of electrical, magnetic, or optical signals capable of being stored, accessed, transferred, combined, compared, or otherwise manipulated by a machine. It is convenient at times, principally for reasons of common usage, to refer to such signals using words such as “data,” “content,” “bits,” “values,” “elements,” “symbols,” “characters,” “terms,” “numbers,” “numerals,” or the like. These words, however, are merely convenient labels and are to be associated with appropriate physical quantities.

Unless specifically stated otherwise, discussions herein using words such as “processing,” “computing,” “calculating,” “determining,” “presenting,” “displaying,” or the like may refer to actions or processes of a machine (e.g., a computer) that manipulates or transforms data represented as physical (e.g., electronic, magnetic, or optical) quantities within one or more memories (e.g., volatile memory, non-volatile memory, or a combination thereof), registers, or other machine components that receive, store, transmit, or display information.

As used herein any reference to “one embodiment” or “an embodiment” means that a particular element, feature, structure, or characteristic described in connection with the embodiment is included in at least one embodiment. The appearances of the phrase “in one embodiment” in various places in the specification are not necessarily all referring to the same embodiment.

Some embodiments may be described using the expression “coupled” and “connected” along with their derivatives. It should be understood that these terms are not intended as synonyms for each other. For example, some embodiments may be described using the term “connected” to indicate that two or more elements are in direct physical or electrical contact with each other. In another example, some embodiments may be described using the term “coupled” to indicate that two or more elements are in direct physical or electrical contact. The term “coupled,” however, may also mean that two or more elements are not in direct contact with each other, but yet still co-operate or interact with each other. The embodiments are not limited in this context.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

In addition, use of the “a” or “an” are employed to describe elements and components of the embodiments herein. This is done merely for convenience and to give a general sense of the invention. This description should be read to include one or at least one and the singular also includes the plural unless it is obvious that it is meant otherwise.

Upon reading this disclosure, those of skill in the art will appreciate still additional alternative structural and functional designs for a system and a process for performing form analysis through the disclosed principles herein. Thus, while particular embodiments and applications have been illustrated and described, it is to be understood that the disclosed embodiments are not limited to the precise construction and components disclosed herein. Various modifications, changes and variations, which will be apparent to those skilled in the art, may be made in the arrangement, operation and details of the method and apparatus disclosed herein without departing from the spirit and scope defined in the appended claims.

What is claimed is:

1. A method for determining building damage potential, the method comprising:
inputting building characteristics for a building into a machine learning model configured to output a probability that a given building will be lost should a fire reach the building;
receiving, as output from the machine learning model, building loss factor for the building;
determining an exposure measurement for the building by performing a plurality of simulations that simulate, over a plurality of candidate environmental parameters, whether a simulated fire would encroach on the building, and smoothing results of the plurality of simulations;
determining a building damage potential measurement based on the building loss factor, the exposure measurement, and an intensity measurement; and
generating for display a graphical user interface showing fire risk for the building based on the building damage potential measurement.

2. The method of claim 1, wherein the machine learning model is trained using training examples, the training examples each having given characteristics of given buildings as paired with labels indicating whether the given buildings were lost during a historical fire.

3. The method of claim 2, wherein whether the given buildings were lost during a historical fire is determined based on whether the given buildings were impacted by the historical fire beyond a burn scar from the historical fire.

4. The method of claim 2, wherein the given characteristics comprise one or more of building properties, fields surrounding the buildings, landscape properties surrounding the buildings, and building density.

5. The method of claim 1, further comprising:
generating a database comprising the building loss factor, the exposure measurement, and the intensity measurement; and
retrieving the building loss factor, the exposure measurement, and the intensity measurement from the database in order to determine the building damage potential measurement.

6. The method of claim 5, wherein values in the database are made current through a refresh operation.

7. The method of claim 1, wherein the exposure measurement is based on a percentage of the plurality of simulations where the simulated fire reached the building.

8. The method of claim 1, wherein the intensity measurement is determined by simulating a conditional flame length over a plurality of environmental conditions.

9. A non-transitory computer-readable medium comprising memory with instructions encoded thereon, the instructions, when executed by one or more processors, causing the one or more processors to perform operations, the instructions comprising instructions to:
input building characteristics for a building into a machine learning model configured to output a probability that a given building will be lost should a fire reach the building;
receive, as output from the machine learning model, building loss factor for the building;
determine an exposure measurement for the building by performing a plurality of simulations that simulate, over a plurality of candidate environmental parameters, whether a simulated fire would encroach on the building, and smoothing results of the plurality of simulations;
determine a building damage potential measurement based on the building loss factor, the exposure measurement, and an intensity measurement; and
generate for display a graphical user interface showing fire risk for the building based on the building damage potential measurement.

10. The non-transitory computer-readable medium of claim 9, wherein the machine learning model is trained using training examples, the training examples each having given characteristics of given buildings as paired with labels indicating whether the given buildings were lost during a historical fire.

11. The non-transitory computer-readable medium of claim 10, wherein whether the given buildings were lost during a historical fire is determined based on whether the given buildings were impacted by the historical fire beyond a burn scar from the historical fire.

12. The non-transitory computer-readable medium of claim 10, wherein the given characteristics comprise one or more of building properties, fields surrounding the buildings, landscape properties surrounding the buildings, and building density.

13. The non-transitory computer-readable medium of claim 9, further the instructions further comprise instructions to:
generate a database comprising the building loss factor, the exposure measurement, and the intensity measurement; and
retrieve the building loss factor, the exposure measurement, and the intensity measurement from the database in order to determine the building damage potential measurement.

14. The non-transitory computer-readable medium of claim 13, wherein values in the database are made current through a refresh operation.

15. The non-transitory computer-readable medium of claim 9, wherein the exposure measurement is based on a percentage of the plurality of simulations where the simulated fire reached the building.

16. The method of claim 1, wherein the intensity measurement is determined by simulating a conditional flame length over a plurality of environmental conditions.

17. A system for determining building damage potential, the system comprising:
memory with instructions encoded thereon; and
one or more processors that, when executing the instructions, are caused to perform operations comprising:
accessing a building loss factor measurement for a building, the building loss factor measurement determined by:
inputting building characteristics for the building into a machine learning model; and
receiving, as output from the machine learning model, the building loss factor measurement;
accessing an exposure measurement for the building, the exposure measurement determined by performing a plurality of simulations that simulate, over a plurality of candidate environmental parameters, whether a fire would encroach on the building, and smoothing results of the plurality of simulations;
determining a building damage potential measurement based on the building loss factor, the exposure measurement, and an intensity measurement; and
generating for display a graphical user interface showing fire risk for the building based on the building damage potential measurement.

18. The system of claim 17, wherein the machine learning model is trained using training examples, the training examples each having given characteristics of given buildings as paired with labels indicating whether the given buildings were lost during a historical fire.

19. The system of claim 17, wherein the exposure measurement is based on a percentage of the plurality of simulations where the simulated fire reached the building.

20. The system of claim 17, wherein the intensity measurement is determined by simulating a conditional flame length over a plurality of environmental conditions.
